(19) United States
(12) Patent Application Publication
(10) Pub. No.: US 2026/0191066 A1
(43) Pub. Date: Jul. 2, 2026

(54) IMPRINT MOLD, METHOD FOR MANUFACTURING SEMICONDUCTOR DEVICE USING THE SAME, AND SEMICONDUCTOR DEVICE

(71) Applicant: Panasonic Intellectual Property Management Co., Ltd., Osaka (JP)

(72) Inventors: YUTO TANAKA, Osaka (JP); KIYOKAZU ITOI, Osaka (JP); DAISUKE SAKURAI, Osaka (JP)

(21) Appl. No.: 19/390,732

(22) Filed: Nov. 17, 2025

(30) Foreign Application Priority Data
Nov. 27, 2024 (JP) 2024-206277

(51) Int. Cl. H01L 23/00

(52) U.S. Cl. CPC H10W 72/012; H10W 72/0112; H10W 72/01235; H10W 72/01255

(57) ABSTRACT

Imprint mold 50 includes first surface 51A, second surface 51B that is opposite to first surface 51A and is an uneven surface, and a plurality of pillars 52 protruding from second surface 51B. Second surface 51B around pillar 52 has a recessed shape recessed toward first surface 51A. Imprint mold 50 is used to provide opening 42 in resist 40 provided on a surface of semiconductor element 10, opening 42 corresponding to a position of electrode terminal 11.

### BACKGROUND

### 1. Technical Field

The present disclosure relates to an imprint mold, a method for manufacturing a semiconductor device using the imprint mold, and a semiconductor device.

### 2. Description of the Related Art

In recent years, as demand for high-speed large-capacity communication increases, semiconductor packages have been increased in integration and semiconductor elements, such as a system LSI, a GPU, a CPU, and a memory, have been increased in number of pins of electrode terminals and narrowed in pitch of the electrode terminals. As a technique for mounting a semiconductor element on a mounting substrate, flip-chip mounting is known.

The flip-chip mounting allows a semiconductor element to be mounted on a mounting substrate by bringing a projecting electrode (bump electrode) formed on an electrode terminal of the semiconductor element into contact with a connection terminal of the mounting substrate, and pressurizing and heating the projecting electrode to connect the electrode terminal and the connection terminal. As the bump electrode, a solder bump is used in many cases.

Unfortunately, as a pitch between electrode terminals is narrowed, a bridge failure is likely to occur in which a solder bump melted and deformed in the pressurizing and heating step during the flip-chip mounting is connected to an adjacent solder bump due to a surface tension.

For this reason, a method for forming a fine metal bump having a sharp shape made of gold, copper, or the like instead of the solder bump is known. This method causes a tip of the bump electrode to be plastically deformed in the above-described pressurizing and heating step, thereby bonding the projecting electrode to the connection terminal by solid-phase diffusion. Then, the fine metal bump is not melted during the flip-chip mounting, so that a bridge failure due to melting and deformation can be prevented from occurring to facilitate narrowing of a pitch between electrode terminals.

Known examples of the method for forming a fine metal bump include a method in which a photoresist is applied onto a semiconductor element to form an opening in the photoresist, and then metal is deposited in the opening by plating or the like. The fine metal bump is obtained by removing the resist after deposition of the metal. An example of a method for forming the fine metal bump into a sharp shape is disclosed in PTL 1.

The method disclosed in PTL 1 causes a photoresist to be applied to a semiconductor substrate, the photoresist being subjected to exposure processing for forming an opening and being baked, and specifically provides a temperature gradient to the photoresist to have a higher temperature on a side close to a surface of the photoresist than a side close to the semiconductor substrate. Consequently, the photoresist has a gradient in resistance to a developer in its thickness direction. When development processing is performed using the developer after the baking processing, an opening is formed in the photoresist, the opening having a larger area on the side close to the semiconductor substrate than the side close to the surface of photoresist. When metal is deposited inside the opening by plating and the photoresist is removed, a bump electrode having a sharp shape is obtained.

### CITATION LIST

### Patent Literature

PTL 1: Unexamined Japanese Patent Publication No. 2007-73919

### SUMMARY

To achieve the above object, an imprint mold according to an aspect of the present disclosure includes a first surface, a second surface that is opposite to the first surface and is an uneven surface, and a plurality of pillars protruding from the second surface, in which the second surface includes a plurality of recesses, each of the plurality of recesses is recessed toward the first surface around a corresponding one of the plurality of pillars.

A method for manufacturing a semiconductor device according to an aspect of the present disclosure includes: covering surfaces of a plurality of electrode terminals provided on a semiconductor element with a resist; pressing and pressurizing the imprint mold against the resist to form a plurality of openings in the resist; curing the resist by irradiating the resist with light while heating the semiconductor element covered with the resist after the plurality of openings is formed; and expanding diameters of the plurality of openings using a developer. The pressing and pressuring the imprint mold against the resist is performed such that the second surface brings into contact with a surface of the resist while each of tips of the plurality of pillars is overlapped with a respective one of the plurality of electrode terminals when viewed from above. Then, the curing the resist is performed such that the light enters the inside of the resist according to a shape of the uneven surface transferred to the surface of the resist, and solubility of the resist around each of the plurality of openings in the developer changes in a depth direction of each of the plurality of openings.

A semiconductor device according to an aspect of the present disclosure includes: a semiconductor element having a surface provided with a plurality of electrode terminals; and a resist provided covering the surface and having a plurality of openings. At least one of the plurality of openings overlaps one of the plurality of electrode terminals when viewed from above the surface of the resist and reaches the one of the plurality of electrode terminals. The surface of the resist is an uneven surface having a plurality of protrusions each of which surrounds a corresponding one of the plurality of openings. The plurality of openings each include a second part and a first part in a thickness direction of the resist in sectional view, the second part having a wide width along the surface and the first part having a narrower width than the second part.

### BRIEF DESCRIPTION OF THE DRAWINGS

FIG. 1A is a schematic diagram for illustrating structure of a first imprint mold according to an exemplary embodiment;

FIG. 1B is a schematic diagram for illustrating structure of a second imprint mold;

FIG. 1C is a schematic diagram for illustrating structure of a third imprint mold;

FIG. 2A is a schematic sectional diagram for illustrating a method for manufacturing the first imprint mold;

FIG. 2B is a schematic sectional diagram for illustrating another method for manufacturing the first imprint mold;

FIG. 3A is a schematic sectional diagram for illustrating a method for manufacturing a semiconductor device using the first imprint mold;

FIG. 3B is a schematic sectional diagram for illustrating a step subsequent to a step illustrated in FIG. 3A;

FIG. 3C is a schematic sectional diagram for illustrating a step subsequent to the step illustrated in FIG. 3B;

FIG. 4 is a schematic sectional diagram for illustrating a resist curing step when the first imprint mold is used;

FIG. 5A is a schematic sectional diagram illustrating a resist curing step when the second imprint mold is used;

FIG. 5B is a schematic sectional diagram for illustrating a resist curing step when the third imprint mold is used;

FIG. 6A is a schematic diagram for illustrating structure of an opening when the second imprint mold is used;

FIG. 6B is a schematic diagram for illustrating structure of an opening when the third imprint mold is used;

FIG. 7A is a schematic sectional diagram of a bump electrode according to a first modification;

FIG. 7B is a schematic sectional diagram of another bump electrode according to the first modification;

FIG. 8A is a schematic plan view of a resist provided with an opening according to a second modification;

FIG. 8B is a sectional view taken along line VIIIB-VIIIB in FIG. 8A; and

FIG. 9 is a schematic sectional diagram of a bump electrode according to the second modification.

### DETAILED DESCRIPTIONS

When the semiconductor element has a large area in the conventional method disclosed in PTL 1, it is difficult to suppress temperature variation in the surface of the semiconductor element during baking. In this case, developer resistance of the photoresist varies in the surface in accordance with the variation in baking temperature. As a result, not only the opening but also the tip of the bump electrode varies in shape in the surface of the semiconductor element. When the shape varies, a connection state between the bump electrode and the connection terminal is not stabilized during flip-chip mounting, and thus connection reliability may be impaired.

The present disclosure has been made in view of such a point, and it is an object of the present disclosure to provide an imprint mold used for uniformly and stably forming a bump electrode provided on an electrode terminal in a semiconductor element with a large area, a method for manufacturing a semiconductor device using the imprint mold, and the semiconductor device.

Hereinafter, an exemplary embodiment of the present disclosure will be described with reference to the drawings. The description below of a preferred exemplary embodiment is merely exemplary in nature, and is not intended to limit the present disclosure, its application, or its use.

### Exemplary Embodiment

### Structure of Imprint Mold

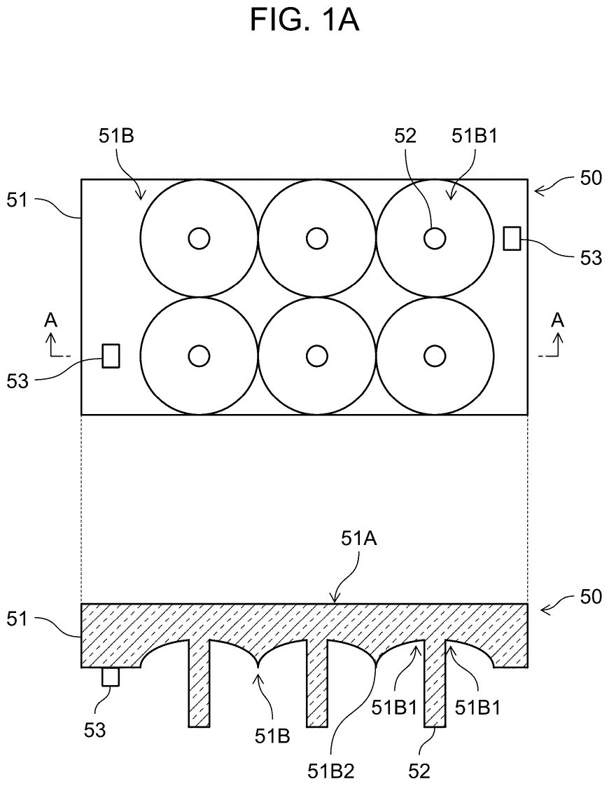

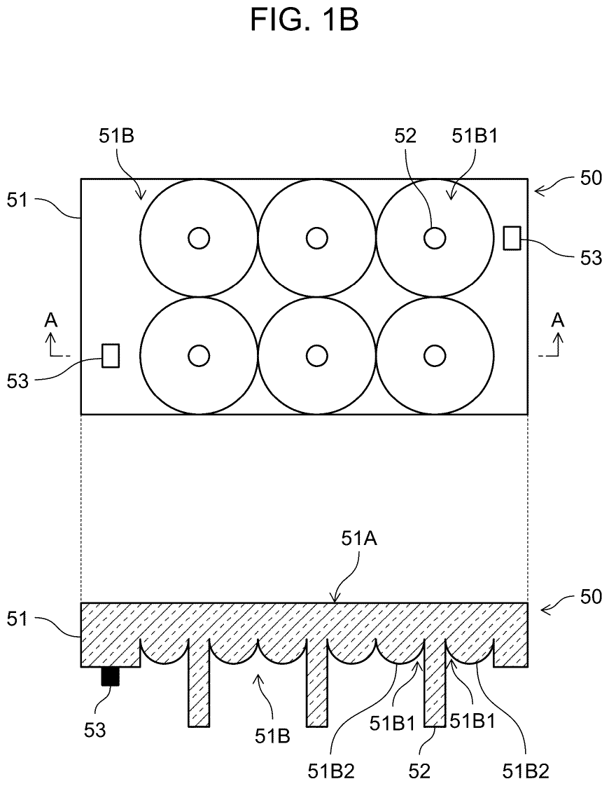

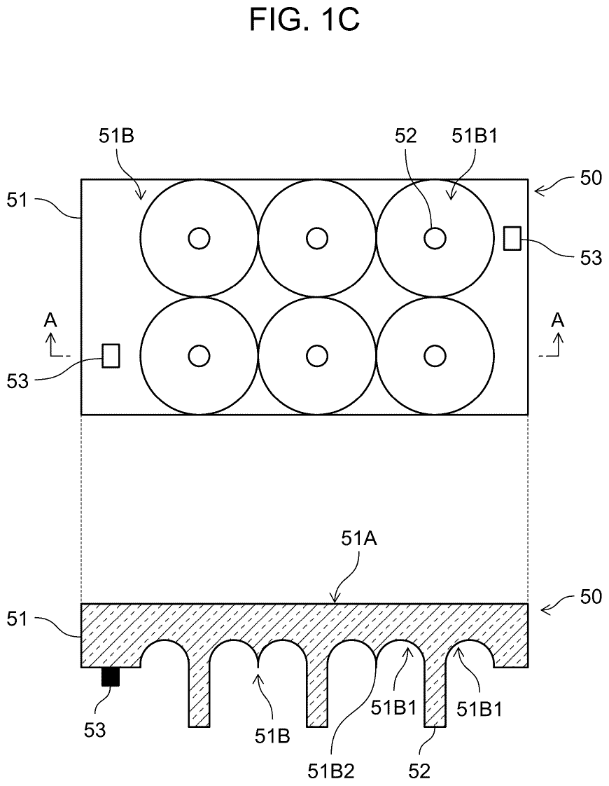

FIG. 1A is a schematic diagram for illustrating structure of a first imprint mold according to an exemplary embodiment. FIG. 1B is a schematic diagram for illustrating structure of a second imprint mold. FIG. 1C is a schematic diagram for illustrating structure of a third imprint mold.

FIGS. 1A to 1C each include an upper view that is a view of imprint mold 50 as viewed from below, and a lower view that is a sectional view taken along line A-A in the upper view. The upper view in each of FIGS. 1A to 1C may be referred to as a plan view. The lower view in each of FIGS. 1A to 1C may be referred to as a sectional view.

FIGS. 1A to 1C each illustrate pillars 52 that are simplified in number and placement, and that are different in number and placement from actual pillars.

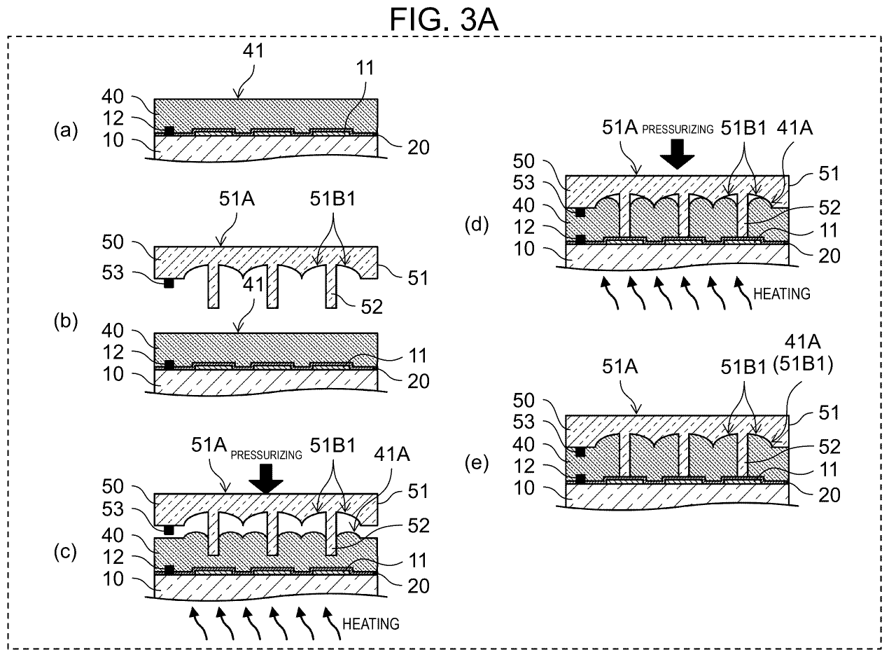

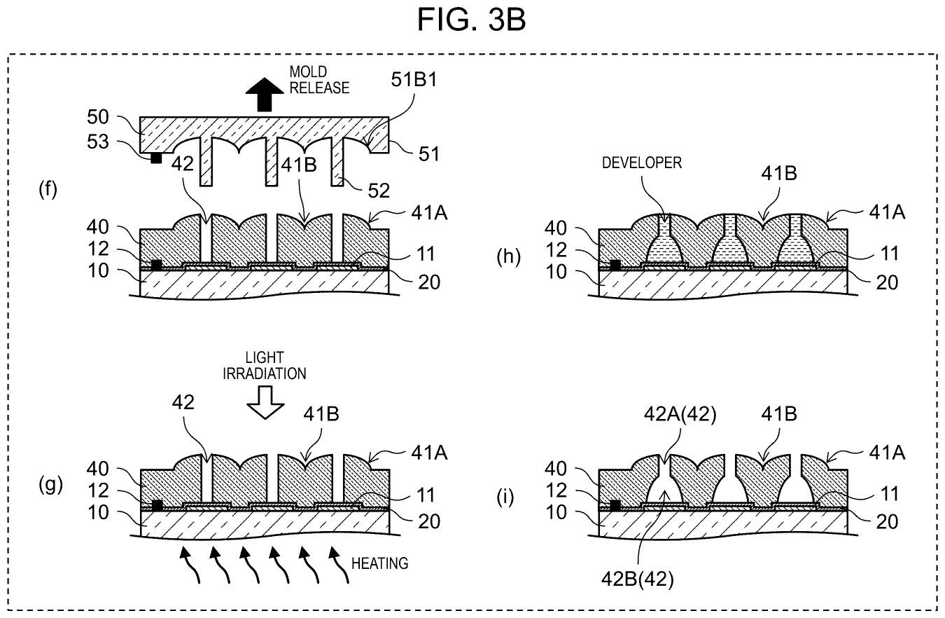

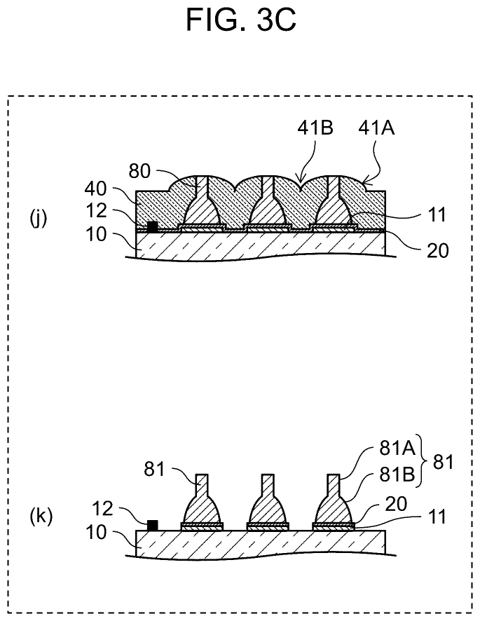

The following description shows a side on which first surface 51A of imprint mold 50 is disposed and that may be referred to as an upper side or an upper part, and a side on which second surface 51B is disposed and that may be referred to as a lower side or a lower part. For the semiconductor element 10 (FIGS. 3A to 3C) provided with the resist 40, a side on which the resist 40 is disposed may be referred to as an upper side or an upper part, and a side on which the semiconductor element 10 is disposed may be referred to as a lower side or a lower part.

First to third imprint molds 50A, 50B, and 50C illustrated respectively in FIGS. 1A to 1C each include body 51 in a plate shape and a plurality of pillars 52. Body 51 includes first surface 51A and second surface 51B opposite to the first surface. In the present exemplary embodiment, first surface 51A is an upper surface of body 51. Then, second surface 51B is a lower surface, and is an uneven surface including recess 51B1 and protrusion 51B2. In the following description, first to third imprint molds 50A, 50B, and 50C may be collectively referred to as imprint mold 50. Even in this case, first surface 51A, second surface 51B, recess 51B1, and protrusion 51B2 are designated.

Pillar 52 is a columnar member protruding downward from second surface 51B, and is formed integrally with body 51. Although pillar 52 has a circular section orthogonal to its longitudinal direction in the present exemplary embodiment, the section is not particularly limited to the circular shape. For example, the shape may be a regular polygon.

Pillars 52 provided on second surface 51B correspond in number and placement to electrode terminals 11 provided on semiconductor element 10 described later.

FIG. 1A illustrates first imprint mold 50A in which recess 51B1 has a semicircular shape centered on pillar 52 in a sectional view. That is, recess 51B1 has a hemispherical shape. Protrusion 51B2 is located at a boundary between recesses 51B1 adjacent to each other.

FIG. 1B illustrates second imprint mold 50B in which protrusion 51B2 has a semicircular shape provided in contact with a base end of pillar 52 in a sectional view. That is, protrusion 51B2 has a hemispherical shape, and two protrusions are provided between pillars 52 adjacent to each other. Recess 51B1 is located at a boundary between protrusions 51B2 adjacent to each other. Recess 51B1 is located at a boundary between protrusion 51B2 and pillar 52 adjacent to the protrusion.

FIG. 1C illustrates third imprint mold 50C in which recess 51B1 has a semicircular shape provided in contact with a base end of pillar 52 in a sectional view. That is, recess 51B1 has a hemispherical shape, and two recesses are provided between pillars 52 adjacent to each other. Protrusion 51B2 is located at a boundary between recesses 51B1 adjacent to each other.

That is, any of imprint molds 50 illustrated in FIGS. 1A to 1C includes recess 51B1 that is provided for each of the plurality of pillars 52 while surrounding the base end of pillar 52.

Each of imprint molds 50 illustrated in FIGS. 1A to 1C is provided with recognition mark 53. Not only the size and shape of recognition mark 53, and the number of recognition marks 53, but also a position of recognition mark 53 with respect to body 51, is not particularly limited to the examples illustrated in FIGS. 1A to 1C. As will be described in detail later, recognition mark 53 is used to align imprint mold 50 and semiconductor element 10.

### Method for Manufacturing Imprint Mold

Material of imprint mold 50 can be variously selected. For example, the material of imprint mold 50 may be a light transmissive resin such as an acrylic resin or a silicone resin, or may be an inorganic insulating material such as glass or silicon (Si). The material of imprint mold 50 may be also a metal material such as nickel.

As will be described later, imprint mold 50 needs to allow light to pass therethrough. Thus, the material of imprint mold 50 is more preferably an acrylic resin or a silicone resin from the viewpoint of light transmittance, processability, and thermal conductivity. For the material, imprint mold 50 can be formed by electron beam machining or laser machining using two-photon absorption. Hereinafter, description will be given with reference to the drawings.

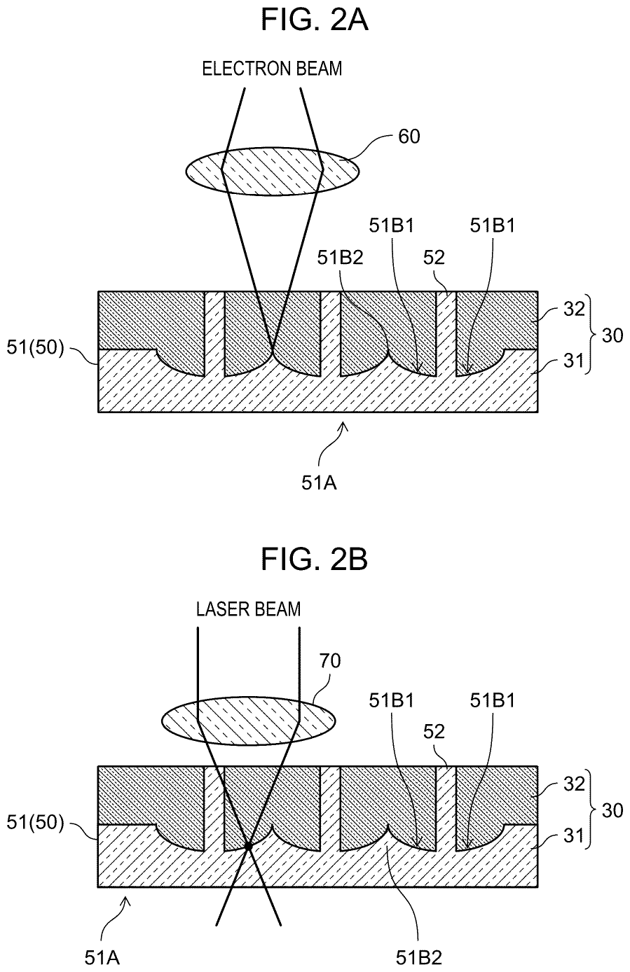

FIG. 2A is a schematic sectional diagram for illustrating a method for manufacturing the first imprint mold. FIG. 2B is a schematic sectional diagram for illustrating another method for manufacturing the first imprint mold.

The method illustrated in FIG. 2A is performed in which light transmissive resin 30 is applied to a base (not illustrated) and flattened, and then irradiated with an electron beam (referred to below as a convergent beam) converged by first lens 60 for an electron beam. A part irradiated with the convergent beam is cured to become cured part 31, so that resistance to an organic solvent is enhanced. That is, the part is less likely to be dissolved in the organic solvent. In contrast, uncured part 32 that allows penetration of the electron beam but is not irradiated with the convergent beam has low resistance to the organic solvent and is likely to be dissolved. As the organic solvent, a developer is used, for example.

Light transmissive resin 30 is irradiated with an electron beam along a predetermined trajectory to form cured part 31 into the shape of first imprint mold 50A. In the irradiation, a focal point of the convergent beam is moved in a thickness direction of light transmissive resin 30 to enable the uneven shape of second surface 51B and the shape of pillar 52 to be formed.

After the formation of cured part 31 is completed, light transmissive resin 30 is impregnated with the developer to dissolve uncured part 32 in the developer, and thus cured part 31 remains. The developer remaining on a surface of cured part 31 is removed and dried to complete first imprint mold 50A.

As illustrated in FIG. 2B, a laser beam may be used instead of the electron beam. For irradiation with the laser beam, the laser beam is condensed by second lens 70 that is an optical lens, and two-photon absorption is generated only near a focal point. As a laser light source, a femtosecond laser is usually used.

The method illustrated in FIG. 2A enables first imprint mold 50A to be formed with processing accuracy on the order of nanometers due to electrons each having a wavelength on the order of nanometers. When two-photon absorption of a laser beam is used as illustrated in FIG. 2B, the laser beam can have a wavelength equal to or less than a wavelength of visible light. Thus, first imprint mold 50A can be formed with processing accuracy on the order of submicron order. For example, when pillar 52 has a diameter of about 1 μm to several μm, the methods illustrated in FIGS. 2A, 2B enable pillar 52 with a desired diameter to be accurately formed.

Although first imprint mold 50A has been described as an example in FIGS. 2A, 2B, imprint mold 50 having another shape, such as second imprint mold 50B or third imprint mold 50C, can also be formed by a similar method.

The method for manufacturing imprint mold 50 made of a light transmissive resin material is not particularly limited to the methods illustrated in FIGS. 2A, 2B. For example, imprint mold 50 may be formed as follows: preparing an original plate (not illustrated) to which the shape of imprint mold 50 has been transferred; pouring the light transmissive resin material into the original plate; curing the material; and releasing the material from the original plate. In this method, the original plate includes a through-hole in a part corresponding to pillar 52. The original plate also has an upper surface provided with a shape acquired by reversing unevenness of second surface 51B. The light transmissive resin is easily released from the original plate by performing treatment such as attaching a mold release agent to the surface of the original plate including the through-hole.

### Method (1) for Manufacturing Semiconductor Device

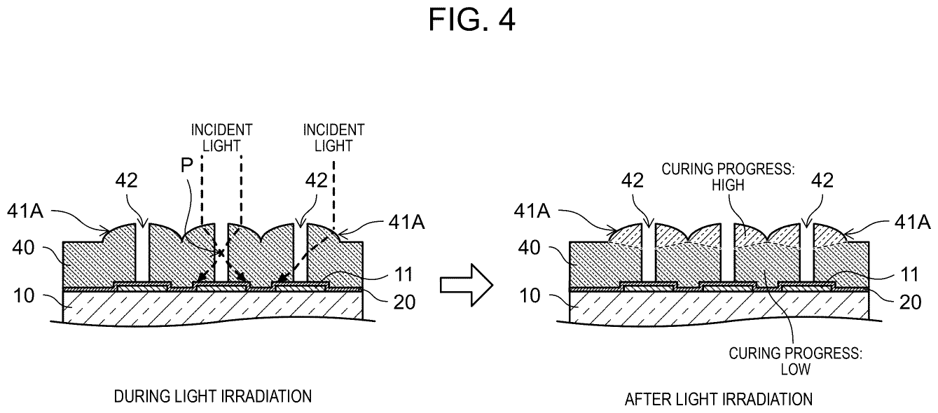

FIG. 3A is a schematic sectional diagram for illustrating a method for manufacturing a semiconductor device using the first imprint mold. FIG. 3B is a schematic sectional diagram for illustrating a step subsequent to a step illustrated in FIG. 3A. FIG. 3C is a schematic sectional diagram for illustrating a step subsequent to the step illustrated in FIG. 3B. FIG. 4 is a schematic sectional diagram for illustrating a resist curing step when the first imprint mold is used.

### Method for Manufacturing Semiconductor Device Provided with Resist having Opening

First, semiconductor element 10 is prepared as illustrated in part (a) of FIG. 3A. Semiconductor element 10 is provided with a plurality of electrode terminals 11 for electrical connection to an external part, such as a connection terminal of a mounting substrate or an interposer, each of which is not illustrated. The semiconductor element 10 is also provided with recognition mark 12. Functions of this configuration will be described later.

Next, seed layer 20 is formed covering the entire surface of semiconductor element 10 including electrode terminal 11 (seed layer forming step). Seed layer 20 is a conductive thin film, and functions as an underlayer when metal is deposited in a plating step described later. Seed layer 20 is preferably made of metal, such as any one of Cu, Ni, Zn, Au, Ag, and Cr, or an alloy containing a plurality of kinds of these metals. When electroless plating is performed in the plating step, seed layer 20 may not be formed.

After seed layer 20 is formed, resist 40 made of a resin material is formed on an upper surface of seed layer 20 (resist forming step). Resist 40 is cured by at least light irradiation. However, a kind of the resin material is not limited to a normal photocurable type, for example. Resist 40 in the present exemplary embodiment is a photothermal combination type that cures using both light irradiation and heating. Resist 40 also contains a photoacid generator. The photoacid generator is a photosensitive agent having a function of generating an acid by being decomposed by light irradiation.

Resist 40 is formed with a uniform film thickness on the surface of semiconductor element 10 by spin coating, dip coating, or screen printing, for example. Resist 40 has a film thickness of about 1 μm to 20 μm, for example, depending on a height of bump electrode 81 described later.

Next, first imprint mold 50A is prepared as illustrated in part (b) of FIG. 3A. First imprint mold 50A and semiconductor element 10 are aligned by an optical method using recognition mark 53 and recognition mark 12 while a tip of pillar 52 faces surface 41 of resist 40. For example, alignment is performed such that the tip of pillar 52 overlaps the center of electrode terminal 11 when viewed from above. When the plurality of pillars 52 overlaps one electrode terminal 11 as viewed from above, alignment is performed such that each of tips of the plurality of pillars 52 aligns with a predetermined position around corresponding electrode terminal 11. When first imprint mold 50A is made of a metal material, recognition mark 53 may be aligned with recognition mark 12 by imaging a space between first imprint mold 50A and semiconductor element 10 with a camera (not illustrated) from laterally.

Next, the tip of pillar 52 is brought into contact with front surface 41 of resist 40 as illustrated in part (c) of FIG. 3A, and first imprint mold 50A is further pressed toward semiconductor element 10 and pressurized (opening forming step). At the same time, semiconductor element 10 including resist 40 is heated. Examples of temperature of the heating include a range from room temperature to 150° C. When pillar 52 is inserted into resist 40, resist 40 is pushed out and swells upward around pillar 52.

When pillar 52 is inserted into resist 40, the tip of pillar 52 may reach a surface of electrode terminal 11, or may be stopped with a gap remaining between the tip of pillar 52 and the surface of electrode terminal 11 by stopping pressurizing pillar 52. When pillar 52 is stopped to be pressurized while having the gap remaining, a contact area between first imprint mold 50A and resist 40 is reduced as compared with when the tip of pillar 52 reaches the surface of electrode terminal 11. Consequently, peeling between seed layer 20 and resist 40 during mold release described later can be prevented.

As illustrated in part (d) of FIG. 3A, when first imprint mold 50A is further pushed toward semiconductor element 10, surface 41 of resist 40 raised around pillar 52 is deformed to come into close contact with second surface 51B. As a result, resist 40 pushed out by pillar 52 is accommodated in recess 51B1 provided in second surface 51B (opening forming step).

When this state is maintained for a predetermined time, recess 51B1 at the base end of pillar 52 is filled with resist 40 without any gap as illustrated in part (e) of FIG. 3A.

Next, first imprint mold 50A is pulled out to be separated from semiconductor element 10, and then is released from resist 40 as illustrated in part (f) of FIG. 3B. As a result, a part into which pillar 52 is inserted becomes opening 42. Surface 41 of resist 40 has a shape to which the unevenness of second surface 51B is transferred. That is, surface 41 of resist 40 includes protrusion 41A at a part corresponding to recess 51B1 of second surface 51B, and recess 41B at a part corresponding to protrusion 51B2 thereof.

Next, resist 40 is cured by irradiating surface 41 of resist 40 with light and heating semiconductor element 10 including resist 40 (resist curing step) as illustrated in part (g) of FIG. 3B. The irradiation light is UV light, for example. At this time, temperature of the heating is in a range nearly equal to a temperature range in the opening forming step.

Resist 40 contains the photoacid generator as described above, so that the photoacid generator is decomposed to generate an acid when resist 40 is irradiated with light. Additionally, resist 40 is heated while being irradiated with light, so that a crosslinking reaction using an acid as a catalyst proceeds to increase crosslinking density at a part close to surface 41.

The part close to surface 41 of resist 40 has a large amount of incident light, and thus the amount of generation of the acid is also increased. Meanwhile, light propagating inside resist 40 is absorbed by resist 40 and attenuated as a propagation distance increases, so that the amount of generation of the acid decreases. That is, the light incident not only from a part around opening 42 but also from surface 41 of resist 40 attenuates as it travels downward, and accordingly, the amount of generation of the acid decreases to lower the crosslinking density.

However, the light passing through the part around opening 42 reaches the surface of semiconductor element 10 without being greatly attenuated by resist 40. For this reason, a difference in the amount of light in a thickness direction of resist 40 is less likely to occur in the part around opening 42, and accordingly, a difference in the crosslinking density is also less likely to occur.

Meanwhile, protrusion 41A is formed on surface 41 around opening 42 of resist 40 as illustrated in part (g) of FIG. 3B at the time when resist 40 is irradiated with light. Protrusion 41A serves as a Fresnel lens for incident light, and refracts light emitted from immediately above toward focal point P illustrated in FIG. 4. As described above, the light emitted from immediately above is refracted or diffused by protrusion 41A around opening 42, so that the amount of light to be originally incident is reduced in a lower part of resist 40. Consequently, a part around opening 42 and near surface 41 includes an upper part with a large amount of incident light in which curing of resist 40 by the crosslinking reaction proceeds to stabilize a shape of a part around and including opening 42 as illustrated in FIG. 4. In contrast, a lower part with a small amount of incident light also has lower crosslinking density than the upper part, so that curing of resist 40 is less likely to proceed.

After the resist curing step is performed, a developer is supplied to surface 41 of resist 40 as illustrated in part (h) of FIG. 3B. A method for supplying the developer can be appropriately selected from known methods. For example, a method (dip) for immersing semiconductor element 10 provided with resist 40 in a tank filled with the developer may be used. Another method (paddle) may be used in which the developer is placed on surface 41 of resist 40 while semiconductor element 10 provided with resist 40 is rotated, and a state is maintained in which the developer is kept stationary using surface tension. Yet another method (spray) may be used in which the developer is sprayed while semiconductor element 10 provided with resist 40 is rotated.

Here, the developer has an action of dissolving the resist 40. As the crosslinking density of resist 40 decreases, a dissolution rate caused by the developer increases. The developer may be tetramethylammonium hydroxide (TMAH) or tetraethylammonium hydroxide (TEAH), for example.

The developer having been supplied flows into opening 42 to dissolve an inner wall of opening 42, so that opening 42 is increased in diameter. Opening 42 before the development opens perpendicularly to surface 41 of resist 40 and is formed to be in a shape uniform in the entire surface of semiconductor element 10.

When the developer is supplied into opening 42, a part of opening 42 close to surface 41 (may be referred to below as a first part 42A) has a high crosslinking density and is sufficiently cured, and thus is substantially maintained in shape before the development although having a diameter slightly increased. Meanwhile, opening 42 is increased in diameter from a position deep to some extent from surface 41 in opening 42 toward semiconductor element 10 as the crosslinking density decreases. A part expanded in diameter may be referred to as second part 42B.

After resist 40 is dissolved by the developer, the developer remaining inside opening 42 is removed by a cleaning liquid as illustrated in part (i) of FIG. 3B. The cleaning liquid may be pure water, alcohol, ethanol, or acetone, for example.

Through the above steps, opening 42 can be formed in resist 40, the opening having second part 42B having a large diameter and first part 42A located above second part 42B and continuously to second part 42B. First part 42A has a smaller diameter than second part 42B. As a result, semiconductor device 90 including resist 40 and semiconductor element 10 can be obtained, the resist including openings 42 reaching respective electrode terminals 11 provided on semiconductor element 10.

### Method (2) for Manufacturing Semiconductor Device

When processing illustrated in FIG. 3C is further performed on semiconductor device 90, bump electrode 81 (see part (k) of FIG. 3C) having a sharp shape can be obtained. Hereinafter, a specific description will be given.

Semiconductor device 90 in a state illustrated in part (i) of FIG. 3B is immersed in a plating bath (not illustrated), and electroplating is performed to precipitate metal plating layer 80 inside opening 42 (part (j) of FIG. 3C). The electrolytic plating bath may be a plating bath capable of bottom-up filling containing a metal salt of Cu or Au, for example. The plating bath capable of bottom-up filling can increase a deposition rate from seed layer 20 located at the bottom of opening 42, and thus is suitable for filling fine openings 42 with metal. As described above, metal plating layer 80 may be deposited inside opening 42 by electroless plating.

When resist 40 is removed by using the developer, an organic solvent, or the like after the plating step is performed, semiconductor device 91 can be obtained in which bump electrode 81 having a sharp shape is formed on the surface of electrode terminal 11 as illustrated in part (k) of FIG. 3C. Bump electrode 81 has the shape reflecting the shape of opening 42, so that bump electrode 81 includes an upper part (may be referred to as third part 81A) having a small diameter as with first part 42A of opening 42, and being perpendicular to the surface of semiconductor element 10. Meanwhile, bump electrode 81 includes a lower part (may be referred to as fourth part 81B) having a shape in which a diameter increases downward in sectional view as with second part 42B of opening 42.

Although not illustrated, seed layer 20 remaining between electrode terminals 11 is removed by dry etching or wet etching after resist 40 is removed. For the removal, a mask for protecting electrode terminal 11 and bump electrode 81 is formed before the etching. After seed layer 20 is removed, the mask is removed.

Consequently, a short circuit between electrode terminals 11 can be prevented. The step of removing seed layer 20 between electrode terminals 11 may be performed before resist 40 is formed.

### Effects and the Like

As described above, imprint mold 50 according to the present exemplary embodiment includes first surface 51A, second surface 51B that is opposite to first surface 51A and is an uneven surface, and the plurality of pillars 52 protruding from second surface 51B. Second surface 51B around pillar 52 has a recessed shape recessed toward first surface 51A.

According to the present exemplary embodiment, when imprint mold 50 is pressed against resist 40 formed on the surface of semiconductor element 10 to pressurize resist 40 toward semiconductor element 10, resist 40 pushed out by pillar 52 is accommodated in recess 51B1 around pillar 52. Consequently, resist 40 around pillar 52 has a protruding shape acquired by transfer of the shape of recess 51B1. Subsequently, when resist 40 is cured by light irradiation, surface 41 of resist 40 having the protruding shape functions as a lens around pillar 52 to enable the amount of incident light to be increased in a part near surface 41 around opening 42. As a result, the curing of resist 40 proceeds to stabilize a shape around and including opening 42. Meanwhile, the amount of incident light can be reduced downward around opening 42, so that resist 40 can be brought into a state of not being sufficiently cured. Consequently, dissolution of a lower part due to the developer proceeds around opening 42 in the developing step subsequent to the resist curing step, so that opening 42 having a sharp shape can be obtained.

Imprint mold 50 is preferably made of a light transmissive material. Consequently, imprint mold 50 and semiconductor element 10 can be accurately aligned by an optical method using recognition mark 53 provided on imprint mold 50 and recognition mark 12 provided on semiconductor element 10. That is, alignment accuracy between the plurality of electrode terminals 11 provided on semiconductor element 10 and the plurality of pillars 52 provided on imprint mold 50 can be enhanced. As a result, opening 42, and eventually bump electrode 81 can be provided in a state of being accurately aligned with corresponding one of the plurality of electrode terminals 11.

Imprint mold 50 is preferably made of a light transmissive resin material. Consequently, imprint mold 50 can be obtained by processing light transmissive resin 30 using a method as illustrated in FIGS. 2A, 2B, for example. Additionally, even when pillar 52 has a diameter on the order of microns or second surface 51B has a complicated uneven shape, imprint mold 50 can be manufactured with high processing accuracy.

A method for manufacturing semiconductor device 90 according to the present exemplary embodiment includes at least a plurality of steps described below.

The resist forming step is performed to cover surfaces of the plurality of electrode terminals 11 provided on semiconductor element 10 with resist 40.

The opening forming step is performed to press and pressurize imprint mold 50 against resist 40 to form opening 42 in resist 40.

The resist curing step is performed to irradiate semiconductor element 10 covered with resist 40 with light after opening 42 is formed, and then heat resist 40 to cure the resist.

The developing step is performed to expand a diameter of opening 42 using a developer.

The opening forming step is performed to press and pressurize imprint mold 50 against resist 40 so that second surface 51B comes into contact with surface 41 of resist 40 and tips of the plurality of pillars 52 overlap respective electrode terminals 11 when viewed from above.

The resist curing step is performed to cause light to enter the inside of resist 40 according to a shape of an uneven surface transferred to surface 41 of resist 40 so that solubility of resist 40 around opening 42 in the developer changes in a depth direction of opening 42.

According to the present exemplary embodiment, the uneven surface provided on second surface 51B of imprint mold 50 is transferred to surface 41 of resist 40. Surface 41 of resist 40 functions as a lens in the resist curing step when light enters the inside of resist 40 according to the shape of the uneven surface, so that the amount of incident light can be changed around opening 42 in the thickness direction of resist 40, that is, in the depth direction of opening 42.

When semiconductor element 10 covered with resist 40 is irradiated with light and then is heated in the resist curing step, the crosslinking reaction can be promoted in accordance with the amount of incident light to increase the crosslinking density. Consequently, a cured state of resist 40 can be changed in accordance with the amount of incident light. As a result, the solubility of resist 40 around opening 42 in the developer changes in the depth direction of opening 42.

Surface 41 of resist 40 has a protruding shape around pillar 52 according to the present exemplary embodiment, so that the amount of incident light can be increased in a part close to surface 41. As a result, the curing of resist 40 proceeds to stabilize a shape around and including opening 42. Meanwhile, the amount of incident light can be reduced downward around opening 42. Consequently, after the resist curing step is performed, resist 40 around opening 42 has a high degree of solubility in the developer in a part close to the surface of electrode terminal 11 and has a low degree thereof in a part close to the surface of resist 40.

As a result, dissolution of a lower part around opening 42 due to the developer proceeds in the developing step, so that opening 42 having a sharp shape can be obtained.

According to the present exemplary embodiment, suppressing a variation in film thickness of resist 40 enables a variation in depth of opening 42 and eventually a variation in height of bump electrode 81 to be also suppressed to the same extent as the variation in film thickness thereof. When resist 40 is formed by the method described above, the variation in film thickness of resist 40 on the surface of semiconductor element 10 can be suppressed to several% or less.

Aligning imprint mold 50 and semiconductor element 10 by an optical method enables pillars 52 to be accurately aligned with respective electrode terminals 11. As a result, alignment accuracy of opening 42 with respect to electrode terminal 11 can be enhanced. For example, when semiconductor element 10 has a size of 30 mm square, misalignment between electrode terminal 11 and pillar 52 can be suppressed to about 1 μm.

Then, the uneven shape of surface 41 of resist 40 is important as a factor for determining a final diameter of opening 42. The uneven shape of surface 41 of resist 40 is determined by the shape of second surface 51B of imprint mold 50, and the shape of opening 42 before development is determined by the shape of pillar 52. Processing resist 40 using imprint mold 50 and appropriately setting conditions in the resist curing step and conditions in the developing step enable forming opening 42 having a stable shape over the entire surface of semiconductor element 10 and having little dimensional variation from an initial design. Examples of the setting conditions in the resist curing step include a wavelength of incident light, the amount of incident light, and light irradiation time. Examples of the setting conditions in the developing step include a type of developer and development time.

Even when second imprint mold 50B illustrated in FIG. 1B or third imprint mold 50C illustrated in FIG. 1C is used, similar effects can be achieved.

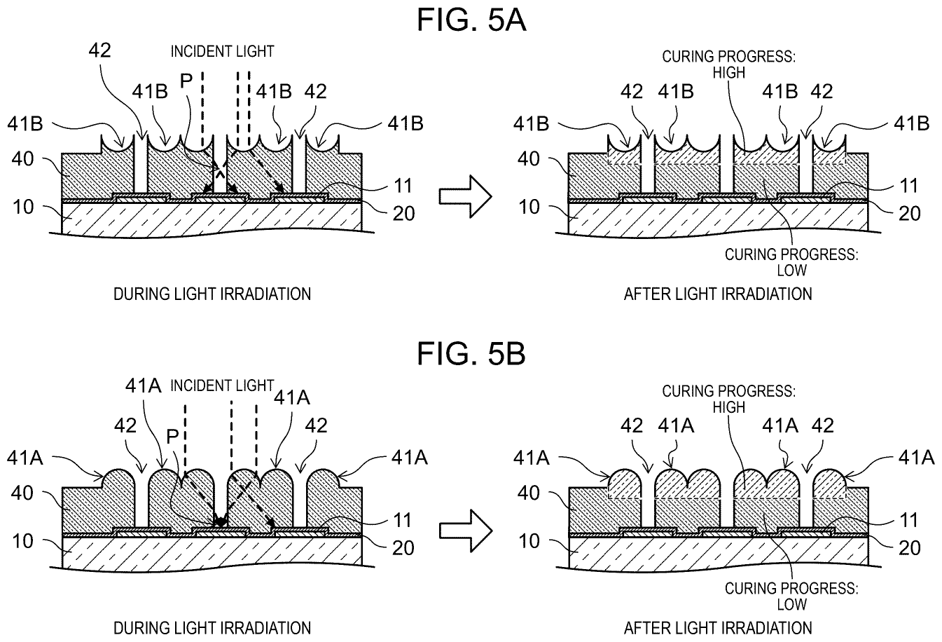

FIG. 5A is a schematic sectional diagram illustrating the resist curing step when the second imprint mold is used. FIG. 5B is a schematic sectional diagram for illustrating the resist curing step when the third imprint mold is used.

As in when first imprint mold 50A is used, the uneven surface transferred to surface 41 of resist 40 functions as a lens in the resist curing step to refract or scatter light incident on surface 41 of resist 40, and then the light enters the inside of resist 40. FIG. 5A illustrates an example in which recess 41B functions as a concave lens for incident light, and refracts the light emitted from immediately above toward focal point P illustrated in FIG. 5A. FIG. 5B illustrates an example in which protrusion 41A functions as a convex lens for incident light, and refracts the light emitted from immediately above toward focal point P illustrated in FIG. 5B.

Consequently, the amount of incident light can be increased in a part close to surface 41 of resist 40 around pillar 52 as illustrated in FIGS. 5A and 5B. As a result, the curing of resist 40 proceeds to stabilize a shape around and including opening 42. Then, the amount of incident light can be reduced downward and solubility of resist 40 in the developer can be increased downward.

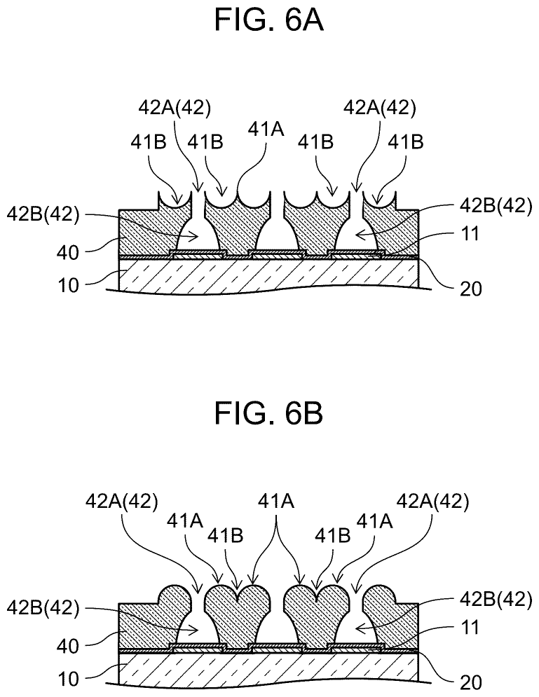

When second imprint mold 50B and third imprint mold 50C are used as illustrated in FIGS. 6A and 6B after the developing step is performed, dissolution of a lower part around opening 42 due to the developer progresses, and thus opening 42 having a sharp shape can be obtained. FIG. 6B illustrates an example in which an upper end of first part 42A of opening 42 has a larger diameter than a part below the upper end.

The opening forming step is preferably performed to press and pressurize imprint mold 50 against resist 40 while semiconductor element 10 covered with resist 40 is heated. Consequently, pillar 52 enters the inside of resist 40 in a state where resist 40 is softened, so that opening 42 can be easily formed.

At this time, surface 41 of resist 40 pushed out by pillar 52 is deformed causing second surface 51B of imprint mold 50 and resist 40 to come into close contact with each other. Consequently, resist 40 pushed out by pillar 52 is accommodated in recess 51B1 provided in second surface 51B.

When surface 41 of resist 40 is deformed as described above, the uneven shape of surface 41 of resist 40 can function as a lens in the resist curing step subsequent to the opening forming step to refract or scatter incident light.

A method for manufacturing semiconductor device 91 according to the present exemplary embodiment further includes steps below with respect to the method for manufacturing semiconductor device 90 described above.

The plating step is performed to plate semiconductor device 90 after the developing step to deposit metal inside opening 42.

A bump electrode forming step is performed to remove resist 40 after the plating step to provide bump electrode 81 on each of the surfaces of the plurality of electrode terminals 11.

Consequently, bump electrode 81 having a sharp shape can be formed while being accurately aligned with corresponding one of the plurality of electrode terminals 11. Additionally, variations in height and diameter of bump electrode 81 can be suppressed. As a result, bridge failure due to melting and deformation during flip-chip mounting of semiconductor device 91 on a circuit board can be prevented from occurring as compared with when metal solder is used, so that narrowing of a pitch between the electrode terminals is easily addressed.

When an electrolytic plating method is used in the plating step, a seed layer forming step of forming seed layer 20 on surfaces of at least the plurality of electrode terminals 11 is preferably provided before the resist forming step.

Semiconductor element 10 having a large area is required to stabilize a shape of bump electrode 81 provided in each of the plurality of electrode terminals 11 as described above. In particular, allowable ranges of a height of bump electrode 81 and misalignment with respect to electrode terminal 11 are narrowed.

According to the present exemplary embodiment, bump electrodes 81 each having a sharp shape and maintaining desired dimensional accuracy and positional accuracy with respect to electrode terminal 11 can be collectively provided in semiconductor element 10 even in such an allowable range. Thus, an increase in the number of pins and a decrease in pitch of electrode terminals 11 can be easily addressed. Consequently, a yield during the flip-chip mounting can be improved. In particular, the method for manufacturing semiconductor device 90, 91 according to the present exemplary embodiment is particularly useful to stably obtain bump electrode 81 having a sharp shape for semiconductor element 10 having an area of several tens of mm² to several hundreds of mm².

Semiconductor device 90 according to the present exemplary embodiment includes at least semiconductor element 10 having a plurality of electrode terminals 11 provided on a surface thereof, and resist 40 provided covering the surface of semiconductor element 10 and having a plurality of openings 42.

Opening 42 is provided overlapping electrode terminal 11 when viewed from above surface 41 of resist 40, and reaching electrode terminal 11.

Surface 41 of resist 40 is an uneven surface having protrusion 41A provided surrounding opening 42.

In sectional view, opening 42 includes second part 42B having a wide width along surface 41 and first part 42A having a narrower width than second part 42B in the thickness direction of resist 40. First part 42A is located above second part 42B continuously to second part 42B.

Semiconductor device 90 is provided with opening 42 having a sharp shape for each of the plurality of electrode terminals 11, opening 42 reaching a surface of corresponding one of the plurality of electrode terminals 11. When metal is deposited to fill the inside of opening 42, semiconductor device 91 including bump electrodes 81 each having a sharp shape and a small variation in height and diameter can be obtained.

### First Modification

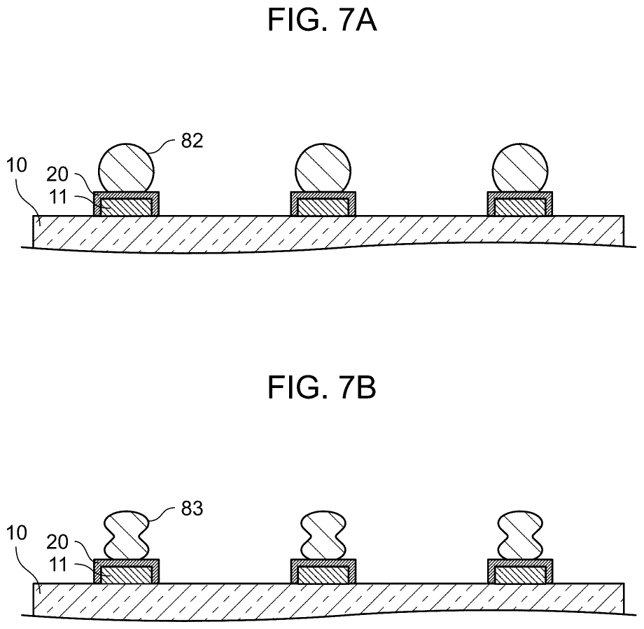

FIG. 7A is a schematic sectional diagram of a bump electrode according to a first modification. FIG. 7B is a schematic sectional diagram of another bump electrode according to a modification. For convenience of description, FIG. 7A and subsequent drawings denote the same parts as those of the first exemplary embodiment with the same reference numerals, and details thereof will not be described.

When the uneven shape of surface 41 of resist 40 is appropriately set as illustrated in FIGS. 4, 5A, and 5B, a position of focal point P for incident light, that is, a distance to opening 42 along the surface of semiconductor element 10 and a depth from surface 41 of resist 40 can be adjusted in the resist curing step. Using this adjustment enables opening 42 and eventually bump electrode 82, 83 to have a desired sectional shape.

For example, bump electrode 82 may have a sectional shape of a circle in which a lower side is cut out as illustrated in FIG. 7A. Bump electrode 83 may have a sectional shape like an hourglass as illustrated in FIG. 7B. To acquire a shape of bump electrode 81 provided on semiconductor element 10, the shape enabling desired flip-chip mounting to be performed, opening 42 and eventually bump electrode 82, 83 can be appropriately changed in shape.

When bump electrode 83 is formed in the shape illustrated in FIG. 7B, stress to be applied to a connection part between bump electrode 83 and electrode terminal 11 during the flip-chip mounting can be reduced, and connection reliability between bump electrode 83 and electrode terminal 11 can be enhanced. As a result, connection reliability between semiconductor element 10 and a circuit board equipped with semiconductor element 10 can be enhanced.

### Second Modification

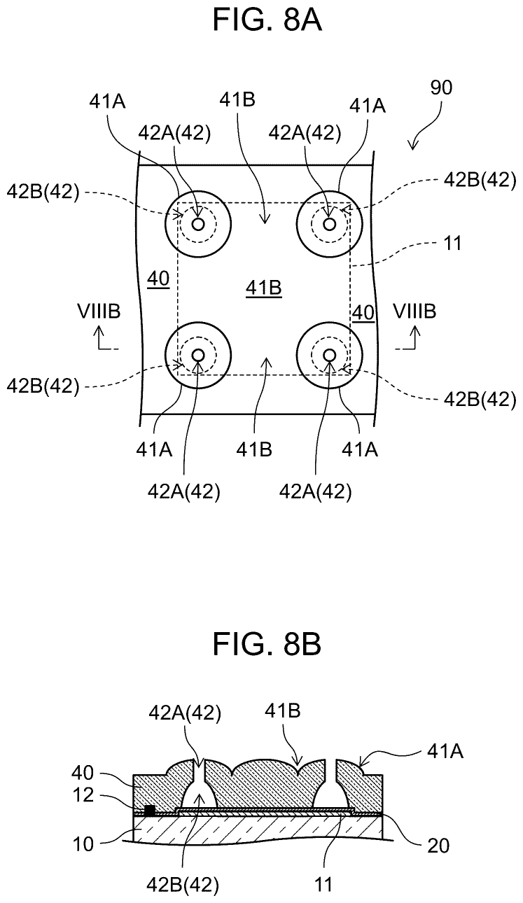

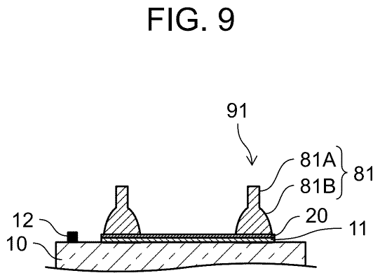

FIG. 8A is a schematic plan view of a resist provided with an opening according to a second modification. FIG. 8B is a sectional view taken along line VIIIB-VIIIB in FIG. 8A. FIG. 9 is a schematic sectional diagram of a bump electrode according to the second modification.

The exemplary embodiment and the first modification each show an example in which one opening 42 is provided on an upper surface of one electrode terminal 11 and an example in which one bump electrode 81 to 83 is provided on the upper surface of one electrode terminal 11. However, a plurality of openings 42, or a plurality of bump electrodes 81, may be provided on the upper surface of one electrode terminal 11 depending on a size of each of electrode terminal 11 and opening 42, and requirements for bonding between electrode terminal 11 and bump electrode 81 to 83. Although FIGS. 8A, 8B show an example in which four openings 42 and four bump electrodes 81 are provided on an upper surface of one electrode terminal 11, the number of openings 42 and bump electrodes 81 provided on the upper surface of the one electrode terminal 11 is not particularly limited to this example. The number can be appropriately changed according to a size of each of electrode terminal 11 and opening 42.

That is, semiconductor device 90 shown in the present modification includes the plurality of openings 42 provided overlapping one electrode terminal 11 when viewed from above the surface of resist 40, and reaching one electrode terminal 11. Semiconductor device 91 shown in the present modification includes the plurality of bump electrodes 81 provided on the upper surface of one electrode terminal 11.

When the plurality of bump electrodes 81 is provided on the upper surface of one electrode terminal 11, a bonding area between bump electrode 81 and a connection terminal of a mounting substrate or an interposer per one electrode terminal 11 can be increased to increase bonding strength. This configuration enables not only improving connection reliability of one electrode terminal 11 to the connection terminal of the mounting substrate or the interposer, but also reducing connection resistance.

Even for a yield even when one of the plurality of bump electrodes 81 has a defect, conduction between electrode terminal 11 and bump electrode 81, and eventually between electrode terminal 11 and the connection terminal of the mounting substrate or the interposer, can be secured to suppress a decrease in the yield at the time of bonding.

### Other Exemplary Embodiments

Another exemplary embodiment can be made by appropriately combining the components shown in the exemplary embodiment and the first and second modifications. For example, the shape of bump electrode 82, 83 shown in the first modification may be applied to the second modification. This configuration causes opening 42 in the second modification to have a shape that also corresponds to the shape of bump electrode 82 or bump electrode 83.

Opening 42 in each of the exemplary embodiment and the first and second modifications has a depth substantially corresponding to a thickness of resist 40, and in a range of about 0.5 μm to 20 μm. Opening 42 includes first part 42A and second part 42B that preferably have a ratio of diameters of about “1:2” to “1:4”.

According to the present disclosure, a bump electrode provided on an electrode terminal and an opening provided in a resist for forming the bump electrode can be uniformly and stably formed on a semiconductor element with a large area in which increase in number of pins of electrode terminals and decrease in pitch of the electrode terminals progress.

The imprint mold of the present disclosure can uniformly and stably form an opening provided in a resist in a semiconductor element with a large area, and is useful for forming a bump electrode provided on each of electrode terminals in which increase in number of pins and decrease in pitch progress.

What is claimed is:

1. An imprint mold comprising:
a first surface;
a second surface that is opposite to the first surface and is an uneven surface; and
a plurality of pillars protruding from the second surface,
wherein the second surface includes a plurality of recesses, each of the plurality of recesses is recessed toward the first surface around a corresponding one of the plurality of pillars.

2. The imprint mold according to claim 1,
wherein the imprint mold contains a light transmissive material.

3. A method for manufacturing a semiconductor device, the method comprising:
covering surfaces of a plurality of electrode terminals provided on a semiconductor element with a resist;
pressing and pressurizing the imprint mold according to claim 1 against the resist to form a plurality of openings in the resist;
curing the resist by irradiating the semiconductor element covered with the resist with light after the plurality of openings is formed, and heating the semiconductor element after irradiating the semiconductor element; and
expanding diameters of the plurality of openings using a developer,
wherein, the pressing and pressurizing the imprint mold against the resist is performed such that the second surface brings into contact with a surface of the resist while each of tips of the plurality of pillars is overlapped with a respective one of the plurality of electrode terminals when viewed from above, and
the curing the resist is performed such that the light enters an inside of the resist according to a shape of the uneven surface transferred to the surface of the resist, and solubility of the resist around each of the plurality of openings in the developer changes in a depth direction of each of the plurality of openings.

4. The method according to claim 3,
wherein after the curing the resist, the resist around each of the plurality of openings has a high degree of solubility in the developer in a part close to the surface of the electrode terminal and has a low degree of solubility in a part close to the surface of the resist.

5. The method according to claim 3,
wherein the curing the resist is performed such that the uneven surface transferred to the surface of the resist functions as a lens to refract or scatter the light incident on the surface of the resist, and then the light enters the inside of the resist.

6. The method according to claim 3,
wherein the pressing and pressuring the imprint mold against the resist is performed while the semiconductor element covered with the resist is heated.

7. The method according to claim 6,
wherein the pressing and pressuring the imprint mold against the resist is performed such that the resist is pushed out by the plurality of pillars to deform the surface of the resist to cause the second surface and the resist to come into close contact with each other, and thus causing the resist to be accommodated in the plurality of recesses provided in the second surface.

8. The method according to claim 3, further comprising:
performing plating after the expanding the diameters of the plurality of openings to deposit metal inside the plurality of openings; and
removing the resist after the performing the plating and providing a plurality of bump electrodes on the surfaces of the plurality of electrode terminals, respectively.

9. A semiconductor device comprising:
a semiconductor element having a surface provided with a plurality of electrode terminals; and
a resist provided covering the surface and including a plurality of openings,
wherein at least one of the plurality of openings overlaps one of the plurality of electrode terminals when viewed from above the surface of the resist and reaches the one of the plurality of electrode terminals,
the surface of the resist is an uneven surface having a plurality of protrusions each of which surrounds a corresponding one of the plurality of openings, and
the plurality of openings each include a second part and a first part in a thickness direction of the resist in sectional view, the second part having a wide width along the surface and the first part having a narrower width than the second part.

10. The semiconductor device according to claim 9,
wherein two or more of the plurality of openings overlap the one of the plurality of electrode terminals when viewed from above the surface of resist, and reach the one of the plurality of electrode terminals.
